(19) United States
(12) Patent Application Publication
(10) Pub. No.: US 2013/0299859 A1
(43) Pub. Date: Nov. 14, 2013

(54) SUBSTRATE FOR OPTICAL SEMICONDUCTOR APPARATUS, METHOD FOR MANUFACTURING THE SAME, OPTICAL SEMICONDUCTOR APPARATUS AND METHOD FOR MANUFACTURING THE SAME

(71) Applicant: SHIN-ETSU CHEMICAL CO., LTD., Tokyo (JP)

(72) Inventors: Satoshi ONAI, Takasaki (JP); Mitsuhiro IWATA, Takasaki (JP); Yoshifumi HARADA, Takasaki (JP); Shinji KIMURA, Annaka (JP)

(73) Assignee: Shin-Etsu Chemical Co., Ltd., Tokyo (JP)

(21) Appl. No.: 13/869,391

(22) Filed: Apr. 24, 2013

(30) Foreign Application Priority Data
May 14, 2012 (JP) 2012-110966

(51) Int. Cl. H01L 33/58; H05K 1/03

(52) U.S. Cl. CPC H01L 33/58; H05K 1/0306
USPC 257/98; 438/26; 174/258; 264/1.7; 427/123

(57) ABSTRACT

The present invention provides a substrate for an optical semiconductor apparatus for mounting optical semiconductor devices, the substrate includes first leads to be electrically connected to first electrodes of the optical semiconductor devices and second leads to be electrically connected to second electrodes of the optical semiconductor devices, wherein the first leads and the second leads are arranged each in parallel, a molded body of a thermosetting resin composition is molded in a penetrating gap between the first leads and the second leads, a reflector of the thermosetting resin composition is molded at a periphery of respective regions on which the optical semiconductor devices are to be mounted, and the resin molded body and the reflector are integrally molded with the first leads and the second leads by injection molding.

### BACKGROUND OF THE INVENTION

1. Field of the Invention

The present invention relates to a substrate for an optical semiconductor apparatus suitable for mounting an optical semiconductor device such as LED and a method for manufacturing the substrate, and an optical semiconductor apparatus using the substrate, and a method for manufacturing the apparatus.

2. Description of the Related Art

An optical semiconductor device such as LED has excellent characteristics of less electric power consumption, so that the applications of the optical semiconductor device for exterior illumination and automobile are increasing in recent years. A surface-mount optical semiconductor apparatus has been used to downsize and thin packages for such applications.

The conventional surface-mount optical semiconductor apparatus has a structure having a first lead which also serves as a pad for mounting an optical semiconductor device, a second lead and a resin molded body (reflector) which supports the leads, and has a role of effectively reflecting light obtained by applying electric current to the optical semiconductor device (for example, see Patent Document 1).

In the surface-mount optical semiconductor apparatus, a thermoplastic resin represented by a polyamide (Nylon series material) or a liquid crystal polymer has been used as a reflector. The thermoplastic resin has an aromatic component in its molecule so that it is poor in light resistance. As the output of an optical semiconductor device has been improved in recent years, there arises a problem in that when it continues to reflect light for a long period of time, it discolors and then becomes black; consequently luminous efficiency of the optical semiconductor apparatus decreases and its lifetime greatly decreases. In addition, since the thermoplastic resin does not have adhesiveness in general, it cannot be adhered to a sealing resin used for protecting the leads and the optical semiconductor device, allowing water, air, and other substance harmful to the optical semiconductor such as sulfur oxide to easily enter into the apparatus. Thus, there is also a problem in that metal, such as silver, which is plated on the surface of the leads to enhance light reflection efficiency is sulfated or oxidized to lower the light reflection efficiency.

To solve the above-mentioned problems, it has been proposed a package substrate for mounting optical semiconductor devices in which a reflector made of a thermosetting resin is molded on a lead frame substrate by transfer molding (for example, see Patent Documents 2 to 4) Each of the package substrates for mounting an optical semiconductor device proposed in these documents is a plane surface-mount substrate in which reflectors having a concave portion are provided in a matrix state and leads which also serve as pads for mounting optical semiconductor devices are disposed on the bottom surface of the concave portion. The manufacturing method of the optical semiconductor apparatus using the substrate has steps in which optical semiconductor devices are mounted and wire bonding is carried out, a sealing material containing a photoconversion material is applied and cured inside the concave portion of the reflectors, and the substrate is diced into pieces to obtain optical semiconductor apparatuses. By the method, the optical semiconductor apparatuses can be industrially manufactured at a low cost.

Also, in the package substrates proposed in the above-mentioned documents, a thermosetting resin is used as the molding resin, so that entering of water, air, and sulfur oxide into the apparatus can be prevented, which is the above-mentioned problem of the substrate using the thermoplastic resin. Further, a resin enhancing in light resistance is used, so that shortening of the lifetime accompanied with discoloration of the resin due to a long period of light reflection can be prevented, and it is utilized as a substrate for manufacturing an optical semiconductor apparatus.

### CITATION LIST

### Patent Literature

[Patent Document 1] JP Japanese Unexamined Patent publication (Kokai) No.H11-087780A
[Patent Document 2] Japanese Patent No. 4608294
[Patent Document 3] JP Japanese Unexamined Patent publication (Kokai) No. 2007-235085A
[Patent Document 4] JP Japanese Unexamined Patent publication (Kokai) No. 2011-009519A

### SUMMARY OF THE INVENTION

In manufacture of the substrate, however, transfer molding, which produces a large amount of cured resin unnecessary for products called “cull” is formed in a resin passage of the mold during molding as well known, is used, so that the method is uneconomical.

In addition, when the transfer molding is carried out, a pressure for pressing the melted thermosetting resin from a plunger at the time of molding is high, so that the thermosetting resin is entered and cured in a minute gap between the leads and the upper and the lower molds to form a thin resin burr (flash burr). The resin burr contaminates the surface of the leads to be utilized for wire bonding connection of the optical semiconductor device, causing failure such as inability to electrically connect between the optical semiconductor device with the leads.

Even if wire bonding is possible, bonding strength of the wire is lowered, and at least the flush burr affects adhesiveness to the sealing material to be used for the protection of the optical semiconductor device. Moreover, the flash burr lowers glossiness of the surface of the lead frame or the metal plating, and reflection efficiency of light emitted from the optical semiconductor apparatus, so that it causes a problem that an optical semiconductor apparatus having high luminance cannot be manufactured stably.

In general, as a method for removing the flash burr, there are a wet blast treatment in which the flash burr is removed by spraying a chemical solution containing fine particles to the surface of the leads after molding the thermosetting resin with a high pressure, a dry blast treatment in which the flash burr is removed by spraying dry fine particles with a high pressure, and a method of physically grinding the surface of the leads. However, all the methods damage the surface of metal such as metal plating represented by, in particular, glossy silver plating, so that the glossiness before removing the burr cannot be maintained. Also, a heat treatment method represented by a laser process, generates heat and the heat causes oxidation or burning on the metal surface; similarly the glossiness before removing the burr cannot be maintained.

As the other method, there is a method in which the burr is peeled off by a high pressure fluid such as a water jet method. This method, however, cannot remove the flash burr sufficiently, so that the object of removing the flash burr cannot be accomplished sufficiently. Moreover, there is also a method in which metal plating is carried out again after removing the burr to recover the glossiness, but the method involves many problems that it is difficult to control the thickness of the plating, the thermosetting resin is discolored by the chemical solution for the plating, and the adhesive surface between the thermosetting resin and the lead in an interface is separated when electric current is applied during the plating process, and an additional process must be added so that it is industrially uneconomical.

The present invention has been accomplished in view of the above-mentioned problems, and its object is to provide a substrate for an optical semiconductor apparatus having high light reflection efficiency in which the generation of a flash burr is inhibited, a method for manufacturing the substrate for an optical semiconductor apparatus with a low cost, an optical semiconductor apparatus using the substrate, and a method for manufacturing the apparatus.

To accomplish the above-mentioned object, the present invention provides a substrate for an optical semiconductor apparatus for mounting optical semiconductor devices, the substrate comprising first leads to be electrically connected to first electrodes of the optical semiconductor devices and second leads to be electrically connected to second electrodes of the optical semiconductor devices, wherein the first leads and the second leads are arranged each in parallel, a molded body of a thermosetting resin composition is molded in a penetrating gap between the first leads and the second leads, a reflector of the thermosetting resin composition is molded at a periphery of respective regions on which the optical semiconductor devices are to be mounted, and the resin molded body and the reflector are integrally molded with the first leads and the second leads by injection molding.

Such a substrate for an optical semiconductor apparatus has high quality in which the generation of a flash burr is inhibited. It also has higher light reflection efficiency and is low-cost.

In the substrate, metal plating having a glossiness of 1.0 or more is preferably applied onto surfaces of the first leads and the second leads.

Such a substrate is more excellent in light reflection efficiency. As mentioned above, in the substrate for an optical semiconductor apparatus of the present invention, the generation of a flash burr is inhibited, so that it is not necessary to carry out a process for removing a burr and the glossiness of the metal plating can be kept high.

Moreover, the first leads and the second leads preferably each have a step, a taper portion or a concave portion at their side surfaces in a thickness direction.

With the leads having such a constitution, the thermosetting resin composition can be held more surely in the gap during the injection molding so that the substrate can be readily manufactured. Also, the strength of the substrate can be improved.

Moreover, the first leads and the second leads arranged each in parallel may be connected to a frame-shaped frame through a tie bar having a thickness thinner than the thicknesses of the first leads and the second leads.

With the leads having such a constitution, it can be readily handled during the injection molding, and the generation of an unfilled portion and a resin burr in the resin molded body near the tie bar can be reduced.

Moreover, the thermosetting resin composition may be at least one selected from the group consisting of a silicone resin, an organic modified silicone resin, an epoxy resin, a modified epoxy resin, an acrylate resin and an urethane resin.

Such a substrate has excellent heat resistance.

Moreover, the cured thermosetting resin contains at least one of an inorganic filler and a diffusing agent, the inorganic filler may be at least one selected from the group consisting of silica, alumina, magnesium oxide, antimony oxide, aluminum hydroxide, barium sulfate, magnesium carbonate and barium carbonate, and the diffusing agent may be at least one selected from the group consisting of barium titanate, titanium oxide, aluminum oxide and silicon oxide.

Such a substrate is excellent in heat resistance, weather resistance and light resistance.

Furthermore, the present invention provides an optical semiconductor apparatus comprising an optical semiconductor device mounted on a first lead of the above substrate for an optical semiconductor apparatus of the present invention, a first electrode and a second electrode of the optical semiconductor devices are electrically connected to the first lead and a second lead, respectively, by wire bonding or flip chip bonding, and the optical semiconductor device is sealed by a resin or subjected to lens molding.

Such an optical semiconductor apparatus has high quality in which the generation of a flash burr is inhibited. It also has higher light reflection efficiency and is low-cost.

Furthermore, the present invention provides a method for manufacturing a substrate for an optical semiconductor apparatus for mounting optical semiconductor devices, the substrate including first leads to be electrically connected to first electrodes of the optical semiconductor devices and second leads to be electrically connected to second electrodes of the optical semiconductor devices, the method comprising arranging the first leads and the second leads each in parallel, and molding a molded body of a thermosetting resin composition in a penetrating gap between the first leads and the second leads, and a reflector of the thermosetting resin composition at a periphery of respective regions on which the optical semiconductor devices are to be mounted by injection molding to integrally mold the resin molded body and the reflector with the first leads and the second leads.

By such a manufacturing method, a substrate for an optical semiconductor apparatus having higher light reflection efficiency in which the generation of a flash burr is inhibited can be readily manufactured with a low cost.

In the method, metal plating having a glossiness of 1.0 or more is preferably applied onto surfaces of the first leads and the second leads.

In such a manner, a substrate for an optical semiconductor apparatus having higher reflection efficiency can be manufactured. As mentioned above, the method for manufacturing the present invention can inhibit the generation of a flash burr so that it is not necessary to carry out a process for removing a burr and the glossiness of the metal plating can be kept high.

Moreover, after the resin molded body and the reflector are molded, the integrally molded substrate for an optical semiconductor apparatus may be subjected to at least one of cleaning treatments of chemical solution cleaning with an acid or an alkali and electrolytic degreasing.

In such a manner, oils and fats attached to the surfaces of the leads and the metal plating can be removed without decreasing the glossiness. Accordingly, adhesiveness of the sealing material in the manufacturing process of an optical semiconductor apparatus can be heightened.

Moreover, the first leads and the second leads having a step, a taper portion, or a concave portion at their side surfaces in a thickness direction are preferably used.

In this manner, the thermosetting resin composition can be held more surely in the gap during the injection molding so that the substrate can be readily manufactured. Also, the strength of the substrate can be improved.

Moreover, the first leads and the second leads may be arranged each in parallel by connecting the first leads and the second leads to a frame-shaped frame through a tie bar having a thickness thinner than a thicknesses of the first leads and the second leads.

In this manner, a substrate for an optical semiconductor apparatus that can be readily handled during the injection molding, and can reduce the generation of an unfilled portion and a resin burr in the resin molded body near the tie bar can be manufactured.

Moreover, the thermosetting resin composition used may be at least one selected from the group consisting of a silicone resin, an organic modified silicone resin, an epoxy resin, a modified epoxy resin, an acrylate resin and an urethane resin.

In this manner, a substrate for an optical semiconductor apparatus excellent in heat resistance can be manufactured.

Moreover, the cured thermosetting resin contains at least one selected from an inorganic filler and diffusing agent, the inorganic filler may be at least one selected from the group consisting of silica, alumina, magnesium oxide, antimony oxide, aluminum hydroxide, barium sulfate, magnesium carbonate and barium carbonate, and the diffusing agent may be at least one selected from the group consisting of barium titanate, titanium oxide, aluminum oxide and silicon oxide.

In this manner, a substrate for an optical semiconductor apparatus excellent in heat resistance, weather resistance and light resistance can be manufactured.

Furthermore, the present invention provides a method for manufacturing an optical semiconductor apparatus comprising mounting an optical semiconductor device on a first lead of the substrate for an optical semiconductor apparatus manufactured by the above method of the present invention electrically connecting a first electrode and a second electrode of the optical semiconductor device to the first lead and a second lead, respectively, by wire bonding or flip chip bonding, and sealing the optical semiconductor device by a resin or subjecting the optical semiconductor device to lens molding.

By such a manufacturing method, an optical semiconductor apparatus having higher reflection efficiency and high quality in which the generation of a flash burr is inhibited can be readily manufactured with a low cost.

According to the present invention, in the method for manufacturing a substrate for an optical semiconductor apparatus, a molded body of a thermosetting resin composition is molded in a penetrating gap between the first leads and the second leads, a reflector of the thermosetting resin composition is molded at a periphery of respective regions on which the optical semiconductor devices are to be mounted, and the resin molded body and the reflector are integrally molded with the first leads and the second leads by injection molding, so that

the generation of a cured resin that is not required in products can be inhibited as little as possible, while the generation of a flash burr at the time of molding the thermosetting resin can be inhibited and a substrate for an optical semiconductor apparatus having higher light reflection efficiency can be readily manufactured with a low cost. Since the substrate for an optical semiconductor apparatus has excellent economic efficiency and high light reflection efficiency, the substrate is useful as a substrate for an optical semiconductor apparatus for mounting an optical semiconductor device, recently used, having a greatly improved output and higher luminance.

### BRIEF DESCRIPTION OF THE DRAWINGS

FIG. 1 is a schematic view of one example of the substrate for an optical semiconductor apparatus of the present invention, in which a top view is shown in (A) and a schematic view of the portion surrounded by a dotted line in (A) is shown at (B);

FIG. 2 is a schematic top view of one example of a lead frame used for the substrate for an optical semiconductor apparatus of the present invention;

FIG. 3 is a schematic sectional view of the portion in the straight line A-A′ direction of FIG. 2;

FIG. 4 is an explanatory view of injection molding in the method for manufacturing the substrate for an optical semiconductor apparatus of the present invention;

FIG. 5 is a schematic sectional view of one example of the optical semiconductor apparatus of the present invention; and

FIG. 6 is an explanatory view of the method for manufacturing the optical semiconductor apparatus of the present invention.

### DETAILED DESCRIPTION OF THE PREFERRED EMBODIMENTS

In the following, embodiments of the present invention will be explained but the present invention is not limited to these embodiments.

As mentioned above, the conventional package substrate for mounting optical semiconductor devices having a thermosetting resin reflector molded on a lead frame substrate by transfer molding has the problems of being uneconomical manufacture by using the transfer molding, generating the flash burr and lowering light reflection efficiency caused by lowering in the glossiness of the leads or the metal plating due to removal of the flash burr, and an additional process making the manufacture uneconomical; therefore there is a need for a substrate for an optical semiconductor apparatus having higher economic efficiency and high metal glossiness.

In view of this, the present inventors have earnestly studied to solve the above-mentioned problems. As a result, they have found that the problems can be solved by molding the reflector and the resin molded body in the penetrating gap between the first leads and the second leads by injection molding to integrally mold these with the first leads and the second leads, bringing the present invention completion.

First, the substrate for an optical semiconductor apparatus of the present invention will be described.

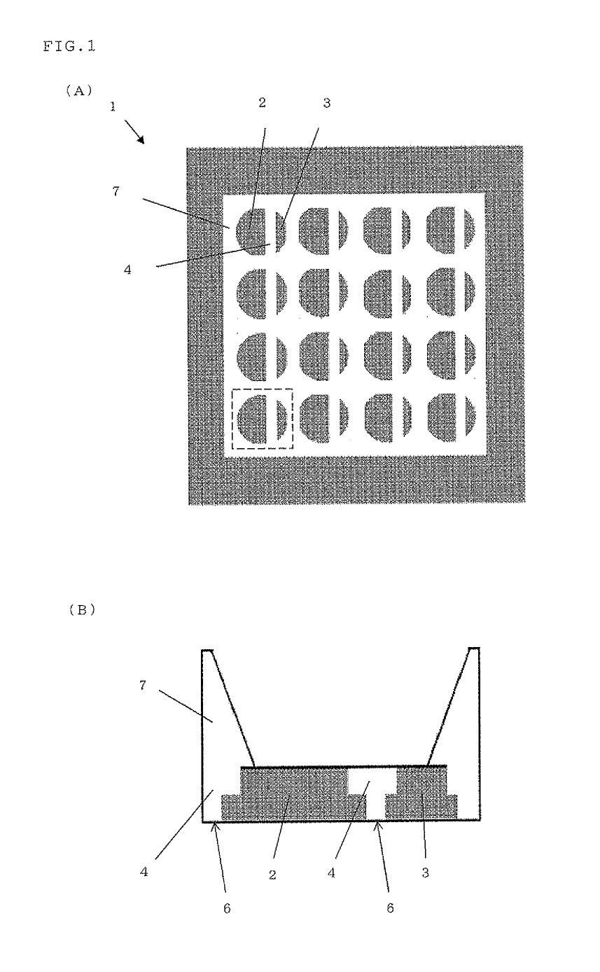

As shown in FIG. 1 at (A) and (B), the substrate 1 for an optical semiconductor apparatus of the present invention has first leads 2 and second leads 3 both made of a metal, a molded body 4 of a thermosetting resin composition, a reflector 7 of the thermosetting resin composition. The first leads 2 are to be electrically connected to the first electrodes of optical semiconductor devices through, for example, wires, and also serve as pads for mounting optical semiconductor devices. The second leads 3 are to be electrically connected to the second electrodes of the optical semiconductor device through, for example, wires.

In the substrate 1 for an optical semiconductor apparatus, the first leads and the second leads are arranged each in parallel.

In the substrate 1, the reflector 7 of the thermosetting resin composition, having light reflective properties, is molded at a periphery of the respective regions on which the optical semiconductor devices are to be mounted, and the molded body 4 of the same thermosetting resin composition as that of the reflector 7 is molded in the penetrating gap 6 between the first leads 2 and the second leads 3. According to this constitution, the resin molded body 4 and the reflector 7 are integrally molded with the first leads 2 and the second leads 3. As shown in FIG. 1 at (B), the reflector 7 has a concave portion to have a role as a light reflective material.

The molded body 4 and the reflector 7 of the thermosetting resin composition are molded by injection molding.

In the substrate for an optical semiconductor apparatus, since the resin molded body 4 and the reflector 7 are molded by injection molding, formation of the cured resin that is not necessary in products at the resin flow passage in the mold during the resin molding can be inhibited as little as possible. This substrate is lower-cost than a substrate for an optical semiconductor apparatus manufactured by using transfer molding. This is because for transfer molding, a large amount of cured resin unnecessary in products is produced as mentioned above. In addition, as described below in detail, since the generation of the flash burr can be inhibited during the resin molding, the substrate can be obtained without a process for removing the flash burr. Thus, the substrate has high light reflection efficiency with high glossiness without lowering the glossiness of the surface of the leads and the metal plating formed on the leads. In addition, it is a high quality substrate molded without an unfilled portion or air remaining of the thermosetting resin.

Further, the back surface of the first leads 2 on which the optical semiconductor devices are to be mounted is exposed so that heat generated by the optical semiconductor devices can be effectively dissipated outside, and, for example, the back surface of the first leads 2 or the second leads 3 can be electrically connected with an external electrode.

As shown in FIG. 1 at (B), at the concave portion of the reflector 7, a taper portion may be provided so that its opening becomes wider upward; thereby, taking out the light to the forward direction can be improved. The angle formed between the bottom surface of the concave portion and the inner surface of the reflector may be so designed that a desired light distribution of the optical semiconductor apparatus is obtained. For example, it is preferably 90° or more and 160° or less, and more preferably 100° or more and 120° or less. When the angle is at 90°, the concave portion is in a cylindrical shape, and for an angle of 150°, the concave portion has an aperture angle of 60°. Also, in consideration with the light reflectivity, the tapered surface is preferably smooth, but a minute unevenness may be provided to improve adhesiveness between the reflector and the sealing resin.

The shape of the outside of the reflector 7 is rectangular, but it may be elliptic, circular, pentagonal or hexagonal. The shape of the main surface side of the concave portion is elliptic, but it may be substantially circular, rectangular, pentagonal or hexagonal. It is preferred to attach a cathode mark at a predetermined position.

Each of the first leads 2, which is not limited as long as it has an area capable of mounting an optical semiconductor devices, preferably has a wide area in the points of thermal conductivity, electro-conductivity and reflection efficiency. Accordingly, the distance between the first lead 2 and the second lead 3 is preferably 0.1 mm or more and 2 mm or less, more preferably 0.2 mm or more and 1 mm or less. When it is 0.1 mm or more, generation of an unfilled portion of the resin molded body 4 can be inhibited. When it is 2 mm or less, an area for mounting the optical semiconductor device on the substrate can be sufficiently broadened.

It is preferred that metal plating is applied onto the surfaces of the first leads 2 and the second leads 3. According to this procedure, reflection efficiency of light emitted from the optical semiconductor device can be heightened without attenuating the light. Also, in the manufacture of the optical semiconductor apparatus, when the optical semiconductor device is sealed by the thermosetting resin or subjected to lens-molding, adhesiveness between the thermosetting resin and the lens material can be heightened.

The metal used for the plating may be conventionally known metal. In particular, silver, gold, palladium, aluminum and an alloy thereof can be used. Silver plating is preferably used since light can be most effectively reflected. These metal plating and alloy plating can be applied by the conventional methods. The metal plating may be formed with a single layer structure or a multilayer structure.

The thickness of the metal plating is generallin the range of 50 μm or less, preferably in the range of 10 μm or less. When it is 50 μm or less, it is economically advantageous. It is preferred to provide plating with high glossiness for the purpose of more enhancing the reflection efficiency of light emitted from the optical semiconductor devices. More specifically, it is preferred to have a glossiness of 1.0 or more, more preferably 1.4 or more. As the metal plating having such a high glossiness, a commercially available chemical solution for plating can be used by a conventionally known methods.

On the surfaces of the first leads 2 and the second leads 3, first plating may be provided for the purpose of improving adhesiveness of the plating. As the first plating, silver plating, gold plating, palladium plating, nickel plating, copper plating, and a strike plating film thereof may be formed, but the present invention is not limited thereto. The film thickness of the first plating is generally 1.0 μm or less. When the thickness is 1.0 μm or less, it is economically advantageous, and it is preferably 0.1 μm or less.

Further, a sulfuration-preventing treatment may be carried out on both the front and back surfaces of the first leads 2 and the second leads 3 to prevent metal sulfuration. This treatment is carried out to prevent light reflectance from decreasing due to a change of color progressed by metal sulfuration as represented by silver plating. The sulfuration-preventing treatment may be carried out, for example, a method in which an alloy or a metal which can prevent sulfuration is plated on the uppermost surface of the leads, a method in which an organic resin is applied or coated on the uppermost surface of the leads with the extent to which wire bonding property is not deteriorated, a method in which a silane coupling agent such as a primer is applied or coated on the uppermost surface of the leads, or a method in which a glass film is arranged on the uppermost surface of the leads with the extent to which wire bonding property is not deteriorated, but the present invention is not limited to these methods and a conventionally known method can be used. The thickness of the sulfuration-preventing film is in a range in which wire bonding connection is not prevented and sulfuration can be prevented, and it is usually 1 μm or less, but the present invention is not particularly limited.

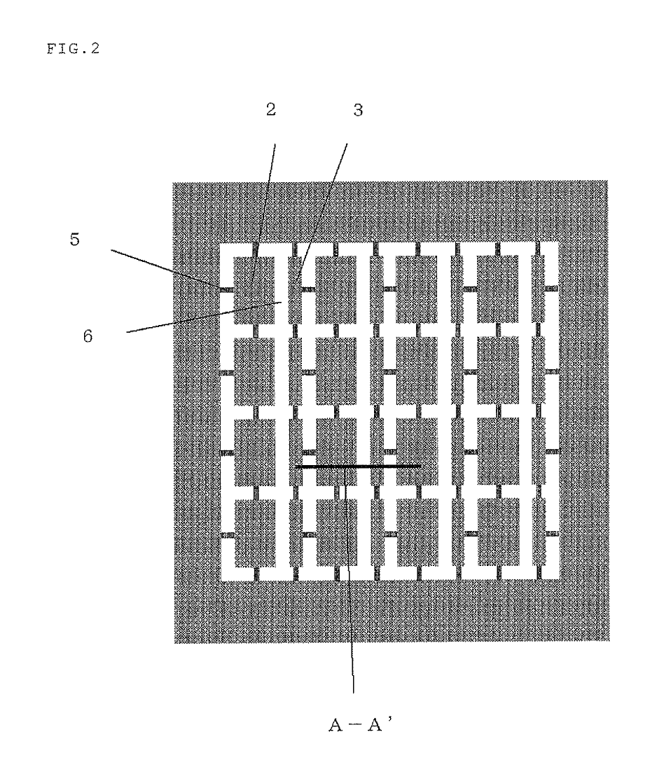

As shown in FIG. 2, the first leads 2 and the second leads 3 arranged each in parallel can be connected to a frame-shaped frame through a tie bar 5 having a thickness thinner than the thicknesses of the first leads and the second leads. More specifically, when the constitution of each one of the first leads 2 and the second leads 3, and the resin molded body 4 therebetween is represented as a unit frame, a plural number of the unit frames are connected by the tie bar 5 in the frame-shaped frame with each other in longitudinal and lateral directions to constitute a lead frame having a multi-unit-frame arrangement. Here, the tie bar 5 for connecting these may be either one or a plural number.

At this time, the thickness of the tie bar 5 is preferably in the range of 1/10(t) to ½(t) with respect to the total thickness (t) of the substrate for an optical semiconductor apparatus, more preferably ½(t) to ⅓(t). The portion at which the tie bar 5 is arranged is a flow passage through which the resin is filled at the time of injection molding. When the thickness is thinner than ½(t), it does not become a resistance to the flow of the resin, and generation of unfilling, void, and burr starting from the tie bar can be inhibited. When the thickness is thicker than 1/10(t), the strength to support the respective leads does not become insufficient and the handling of the lead frame becomes easy to be set and taken out from the mold at the time of molding.

The material of the first leads 2 and the second leads 3 may be copper, a copper alloy of a copper and a metal represented by nickel, zinc, chromium and/or tin is contained in copper, iron, or an iron alloy in which a metal represented by nickel, zinc, chromium and tin. A metal thin plate material, made of the above materials, formed by the conventionally used pressing or etching method can be used, but the present invention is not limited thereto. From the aspects of conductivity, heat dissipation, workability and economic efficiency, copper or the above copper alloy is preferably used. A commercially available product may be used as the above materials, preferably those having a conductivity of 30% IACS or more, more preferably 50% IACS or more.

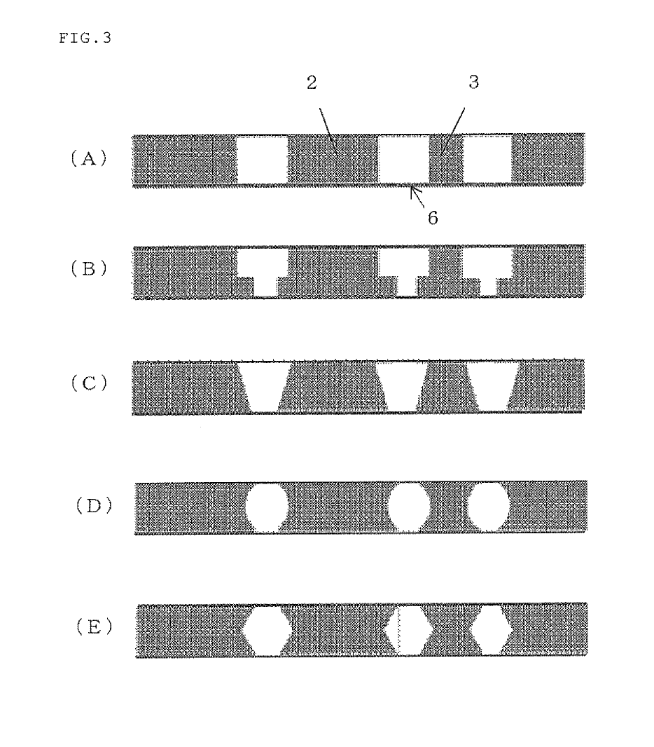

As shown in FIG. 3, the first leads and the second leads preferably each have a step (FIG. 3 at (B)), a taper portion (FIG. 3 at (C)), or a concave portion (at (D) and (E) in FIG. 3) at their side surfaces in the thickness direction. At (B) and (C) in FIG. 3, the steps and the taper portion have a shape extending outward in the direction from the front surface side to the back surface side of the substrate. At (D) and (E) in FIG. 3, the concave portion has a shape bending or curving toward the inside of the side surface. With the side surface having the step, taper portion or concave portion, the thermosetting resin filled at the time of injection molding can be so retained as to not drop from the substrate for an optical semiconductor apparatus.

At this time, it is preferred that the side surface has the step or concave portion, bending shape or curving shape in the viewpoint of increasing a contact area to surely hold the thermosetting resin, and the step is more preferable. The height of the step in the thickness direction is preferably in the range of 1/10(t) to ½(t) with respect to the total thickness (t) of the lead frame, more preferably in the range of ⅕(t) to ½(t). When the height of the step in the thickness direction is thinner than ½(t), it does not become a resistance to the flow of resin when the resin is filled at the time of injection molding, and generation of unfilling, void, and burr starting from the step can be inhibited. When the height of the step in the thickness direction is thicker than 1/10(t), the step do not deform due to insufficient strength and the handling thereof becomes easy.

The thermosetting resin to be used for the resin molded body 4 and the reflector 7 is preferably at least one selected from the group consisting of a silicone resin, a modified silicone resin, an epoxy resin, a modified epoxy resin, an acrylate resin and a urethane resin. Among these, a silicone resin, a modified silicone resin, an epoxy resin and a modified epoxy resin are preferred, more preferably a silicone resin, or a modified silicone resin, and an epoxy resin.

The above-mentioned thermosetting resin may be a resin within the range which is capable of subjecting to injection molding, which may be either a liquid or a solid at the room temperature, and when it is a solid, it can be adjusted to a suitable viscosity capable of subjecting to injection molding by melting it using a special heating and mixing apparatus. In the viewpoint of heightening filling property of the thermosetting resin into a narrow portion, it is preferably a liquid material at room temperature, more preferably in the range of 1 to 100 Pa·s at room temperature. The thermosetting resin preferably has a light reflecting property, and a light reflectance at a wavelength of 450 nm after heat curing is preferably 80% or more, more preferably 90% or more.

The thermosetting resin is preferably those which become hard after curing to retain the shape of the lead frame, and it is preferably a resin excellent in heat resistance, weather resistance and light resistance. To have such a function depending on the purposes, it is preferred that at least one of an inorganic filler and a diffusing agent is added to the thermosetting resin composition to contain these in the cured product. The inorganic filler may be mentioned, for example, silica, alumina, magnesium oxide, antimony oxide, aluminum hydroxide, barium sulfate, magnesium carbonate and barium carbonate, and these materials may be used alone or in combination of two or more. In the aspects of thermal conductivity, light-reflecting characteristics, moldability, flame retardancy, it is preferably silica, alumina, antimony oxide or aluminum hydroxide. In addition, a particle size of the inorganic filler is not particularly limited, and when filling up efficiency with the diffusing agent, and fluidity and filling ability into the narrow portion of the thermosetting resin is considered, it is preferably 100 μm or less. The diffusing agent may be suitably used barium titanate, titanium oxide, aluminum oxide or silicon oxide. A particle size of the diffusing agent is not particularly limited, and when fluidity and filling ability into the narrow portion of the thermosetting resin is considered, it is preferably 100 μm or less.

In addition, depending on the purpose, at least one selected from the group consisting of a pigment, a fluorescent substance and a reflective substance may be mixed.

As these materials, for example, a material in a liquid state and to be used for silicone rubber injection molding is suitable, and there may be mentioned, for example, KEG-2000, KCR-3500 and KCR-4000 (product names), etc., which are products of Shin-Etsu Chemical Co., Ltd., but the present invention is not limited by these.

Next, the method for manufacturing the substrate for an optical semiconductor apparatus of the present invention will be described.

In the manufacturing method of the substrate for an optical semiconductor apparatus of the present invention, the substrate for an optical semiconductor apparatus of the present invention having first leads, second leads, a resin molded body and a reflector is manufactured.

First, for example, as shown in FIG. 2, first leads 2 and second leads 3 are arranged each in parallel. At this time, the first leads and the second leads can be prepared as a lead frame in which the leads are connected to a frame-shaped frame through a tie bar 5. This is preferable since handling of the first leads and the second leads becomes easy.

On the surfaces of the first leads 2 and the second leads 3, metal plating may be applied to enhance the reflection efficiency of light emitted from the optical semiconductor devices as mentioned above. Here, the glossiness of the metal plating is preferably 1.0 or more, more preferably 1.4 or more.

The metal plating may be formed not only the surfaces of the first leads 2 and the second leads 3 but also the entire surface of the first leads and the second leads. For example, a roll-to-roll method or a barrel plating method may be employed.

Incidentally, a sparger system in which a portion not necessary to conduct the plating is covered by a mechanical mask formed by a silicone rubber, etc., and a plating solution is blowing up to the portion to be plated, a taping system in which a masking tape is applied to a portion not necessary to conduct the plating, or an exposure system in which a resist is coated, etc., may be empllyed.

Next, by injection molding, a molded body 4 of a thermosetting resin composition is molded in a penetrating gap between the first leads 2 and the second leads 3, a reflector 7 of the thermosetting resin composition is molded at a periphery of respective regions on which the optical semiconductor devices are to be mounted such that the resin molded body 4 and the reflector 7 are integrally molded with the first leads 2 and the second leads 3.

The distance between the first leads 2 and the second leads 3 is preferably 0.1 mm or more and 2 mm or less and more preferably 0.2 mm or more and 1 mm or less, as mentioned above.

The injection molding is a molding method in which a liquid state resin or a melted resin is injected into the space (product portion) of the mold, and after solidifying it, the resultant product is taken out from the mold, in which the liquid state thermosetting resin with low viscosity can be completely filled into the mold at the time of injection with a lower pressure as compared with the other molding methods. That is, in the molding method in which first leads and second leads are interposed between the upper mold and the lower mold and the resin is injected into the mold, since an injection pressure for the thermosetting resin injected from a nozzle is low, the thermosetting resin does not enter into the minute gap (1 μm or less in some cases) between the leads and the molds; the generation of a flash burr can be inhibited.

In general, as the other molding method using the thermosetting resin, there is, for example, a transfer molding method, but the transfer pressure is high so that the low viscosity thermosetting resin oozed out from the minute gap, and is then cured to become flash burr as mentioned above. In the transfer molding, it is possible to use a release film similarly to the injection molding, but the transfer molding has a problem of a limited range of use because of a structural reason in the molds.

More specifically, the release film cannot be put in the mold to which a resin-injecting passage is ensured, so that it can be applied only to the one side surface. Accordingly, the flash burr is produced at either one of the front or back surface of the substrate for an optical semiconductor apparatus. Moreover, the transfer pressure is high as mentioned above, so that even when the release film is interposed between the mold and the leads, the amount of the flash burr can be reduced but the flash burr cannot be completely eliminated.

As the other molding method, for example, according to the compression molding, the resin can be molded to a predetermined shape, but it is impossible to prevent the resin from flowing into the back surface of the substrate because of arrangement of the mold and the metal plate. Similarly to the transfer molding, the compression molding has the problem of the flash burr and cannot be used.

From these reasons, the injection molding is essential in the present invention, suitable for filling the thermosetting resin into a narrow flow passage, and prevents the flash burr from being produced. The present invention can be accomplished only by using the injection molding.

The molding method of the resin molded body 4 and the reflector 7 by injection molding according to the present invention will be described below more specifically.

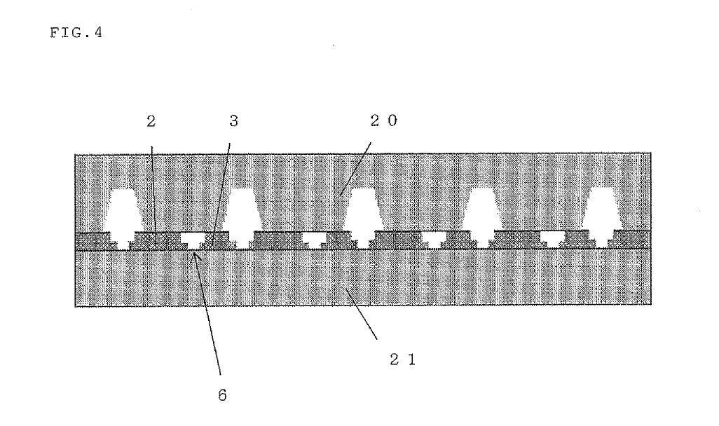

First, as shown in FIG. 4, the first and the second leads are arranged between the upper mold 20 and the lower mold 21. The upper mold 20 has a cavity for molding the reflector.

As the injection molding, either of the insert molding method in which the first and the second leads are directly arranged in the upper and lower molds, and the thermosetting resin composition is injected from a resin inlet of one of the molds, or the in-mold molding method in which a release film is interposed between the molds and the first and the second leads may be used. The in-mold molding is preferable.

In the case of the in-mold molding, by interposing release films among the respective gaps of the upper mold, the lead frame, and the lower mold, without remaining the minute gap between the lead frame and the molds, i.e., the space in the molds can be retained in the state of no gap into which the thermosetting resin can be entered between the lead frame and the molds. Thus, in addition to further inhibiting the flash burr, the metal plating surface can be prevented from being damaged due to the clamping pressure of the molds during the molding. Depending on necessity, a releasing agent may be coated to the molds to easily take out the substrate for an optical semiconductor apparatus from the molds after injection molding.

The thermosetting resin composition injected into the mold is thermally cured preferably under conditions of a temperature of 100° C. to 200° C. for 10 seconds to 300 seconds, then the molds are opened, and the substrate for an optical semiconductor apparatus in which the resin molded body 4 and the reflector 7 are integrally molded with the first leads 2 and the second leads 3 is taken out. Subsequently, depending on necessity, it may be thermally cured for the purpose of completely curing the thermosetting resin under conditions of a temperature of 100° C. to 200° C. for 30 minutes to 10 hours.

After molding the resin molded body and the reflector, the integrally molded substrate for an optical semiconductor apparatus is preferably subjected to cleaning (degreasing) using a chemical solution containing a minimum amount of an acid or an alkali which does not exert any bad effect to the glossiness of the metal surface or electrolytic degreasing, or both of which may be carried out. According to this procedure, a minute amount of oil and fats component attached to the lead by contacting with the upper and lower die or the release film at the time of injection molding can be removed. Moreover, adhesiveness of the sealing material can be improved at the time of sealing the optical semiconductor device by coating the sealing material containing a photoconversion material in the manufacturing step of the optical semiconductor apparatus.

After the above-mentioned cleaning with the chemical solution containing a minimum amount of an acid or an alkali which does not exert any bad effect to the glossiness can be carried out by using a commercially available chemical solution for cleaning, dipping the substrate for an optical semiconductor apparatus therein in the range of within 30 minutes, removing the chemical solution from the substrate for an optical semiconductor apparatus. If it is within 30 minutes, lowering in productivity due to increase in procedural time can be restrained and no bad effect is exerted on the metal plating such as discoloration.

After the electrolytic degreasing treatment can be similarly carried out by using a commercially available cleaning chemical solution for electrolytic degreasing, subjecting to electrolytic treatment with an electric current of 10 A or less for a current passing time of within 5 minutes, removing the chemical solution from the substrate for an optical semiconductor apparatus. More preferred treatment conditions are 5A or less and within 2 minutes. The electric current to be passed may be a direct current or an alternating current, or may be a pulsed current. When the electric current value is 10 A or less and the current passing time is within 5 minutes, there is no fear to cause any inconvenience that the cleaning chemical solution enters into the adhesive surface between the lead and the thermosetting resin to peel of the interface, or it remains to the substrate to discolor the metal plating.

Subsequently, depending on the purposes of enhancing glossiness of the metal plating, plating on the metal surface of the substrate for an optical semiconductor apparatus may be carried out again.

According to the method for manufacturing the substrate for an optical semiconductor apparatus of the present invention, a substrate for an optical semiconductor apparatus having higher light reflection efficiency in which the generation of a flash burr can be inhibited and can be manufactured. Also, the amount of the thermosetting resin used in molding can be reduced so that productivity can be improved. In addition, molding can be carried out without generating an unfilled portion and air remaining of the thermosetting resin.

Next, the optical semiconductor apparatus of the present invention will be described.

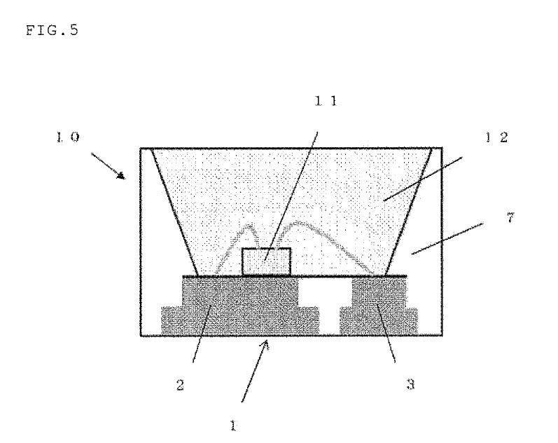

As shown in FIG. 5, in the optical semiconductor apparatus 10 of the present invention, an optical semiconductor device 11 is mounted on the first lead 2 of the substrate 1 for an optical semiconductor apparatus of the present invention, and the first electrode and the second electrode of the optical semiconductor device 11 are electrically connected to the first lead 2 and the second lead 3, respectively, by wire bonding or flip chip bonding. In the concave portion of the reflector 7, a sealing resin 12 is coated to protect the optical semiconductor device 11 and the wire.

Such an optical semiconductor apparatus using the substrate for an optical semiconductor apparatus of the present invention has high quality in which the generation of a flash burr is inhibited, and it has higher light reflection efficiency and is low-cost.

The optical semiconductor apparatus 10 of the present invention can be manufactured by the manufacturing method of the optical semiconductor apparatus of the present invention as mentioned below.

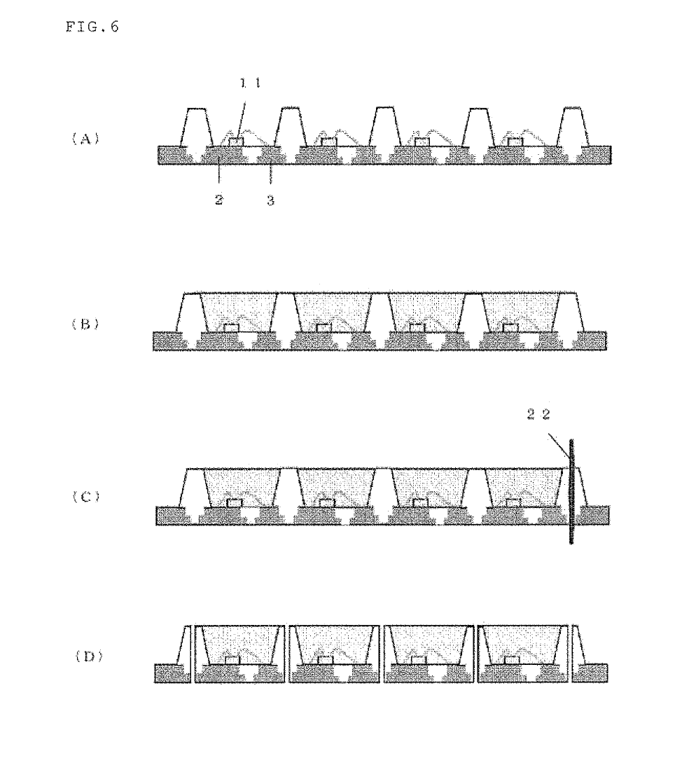

First, the optical semiconductor device 11 is mounted on the first lead 2 which also acts as a pad for mounting the optical semiconductor device 11 thereon (FIG. 6(A)). The first electrode of the optical semiconductor device 11 and the first lead 2 are electrically connected.

The second electrode of the optical semiconductor device 11 and the second lead 3 are electrically connected. This connection is usually carried out by wire bonding, and it may be connected by flip chip bonding depending on the structure of the optical semiconductor device 11.

Depending on necessity, a photoconversion material may be coated on the optical semiconductor device 11. A conventionally known method may be used as the coating method, and it may be optionally selected from a dispensing system, a jet dispensing system, or adhesion of a film, and the like.

Lens molding or coating of a sealing resin is then carried out for the purpose of protecting the optical semiconductor device 11 and the wire (FIG. 6(B)). FIG. 6 shows an example in which the sealing resin is coated. The lens molding can be carried out by using the conventionally known lens material, and in general, it is a thermosetting transparent material, and preferably a silicone resin, for example. As a method of the lens molding, the conventionally known method such as transfer molding, injection molding and compression molding may be used. As the coating method of the sealing resin, a conventionally known method may be used to coat the sealing resin in the concave portion, and a dispense method is generally employed. As the other method, a jet dispense method may be given but the present invention is not limited to these methods.

Next, depending on necessity, the optical semiconductor apparatus is cut by using a dicing blade 22, etc., to divide into pieces (FIG. 6(C)). According to this procedure, an optical semiconductor apparatus having one or more optical semiconductor devices can be obtained (FIG. 6(D)).

As the cutting method, the conventionally known method may be employed and the apparatus can be cut by the conventionally known method such as a dicing process by a rotary blade, a laser processing, a water jet processing and a die processing, and the dicing process is preferred in the aspects of economy and industry.

### EXAMPLES

In the following, the present invention will be described more specifically with reference to Examples of the present invention and Comparative Examples, but the present invention is not restricted thereto.

### Example 1

<Manufacture of Substrate for Optical Semiconductor Apparatus>

A metal plate of a copper alloy containing chromium-tin-zinc with a thickness of 0.3 mm was punched to prepare a lead frame, having a shape shown in FIG. 2, in which first leads and second leads were arranged each in parallel and connected through a tie bar. Also, an etching process was performed to form steps having a height in the thickness direction of 150 μm (½t) at the side surfaces of the first leads and the second leads, as shown at (B) in FIG. 3. Silver plating was then applied to the lead frame as metal plating. The glossiness of the metal plating was measured by using Micro Spectrophotometer VSS400A manufactured by NIPPON DENSHOKU INDUSTRIES Co., LTD. The measured points were five points, and its average value was obtained. As a result, the glossiness was 1.40.

The lead frame was fixed to the lower mold heated to 130° C. The lead frame was interposed with the upper mold heated similarly to 130° C. for mold clamping.

Next, the resin molded body and the reflector were molded by injection molding to integrally mold with the lead frame. More specifically, as the thermosetting resin, KCR-3500 (product name), a liquid injection molding material, made by Shin-Etsu Chemical Co., Ltd., was used, and the thermosetting resin was injected from a nozzle of the injection molding machine. The injected thermosetting resin was heated in the mold at 130° C. for one minute to pre-cure the resin molded body and the reflector. During the injection molding, no cured resin unnecessary for manufacture the substrate for an optical semiconductor apparatus was formed.

Next, the upper mold and the lower mold were opened, the substrate for an optical semiconductor apparatus having the reflector in which the lead frame and the thermosetting resin were integrally molded was taken out from the mold.

After taking out, the thermosetting resin molded body was further heated at 150° C. for 2 hours for complete curing of the thermosetting resin to obtain a substrate for an optical semiconductor apparatus. Degrease cleaning was performed on the substrate for an optical semiconductor apparatus by using an alkaline chemical solution. When the resin molded body and the reflector of the substrate for an optical semiconductor apparatus manufactured as above were examined, they were both molded without an unfilled portion or air remaining of the thermosetting resin.

Furthermore, when the front surface and the back surface of the leads were observed by a scanning electron microscope (SEM), no flash burr was seen. Also, when the glossiness of the metal plating was measured again by using the above-mentioned Micro Spectrophotometer, the glossiness was 1.39, which was substantially not lowered from 1.40 at the time of the plating. As compared with the results of the later-described Comparative Examples 1 to 3, it was confirmed that lowering in glossiness can be restrained.

### <Manufacture of Optical Semiconductor Apparatus>

By using a die bonding agent (KER-3000-M2, product of Shin-Etsu Chemical Co., Ltd.), LED chips, belonging to the same lot, each having a light-emitting layer of InGaN and a main light-emitting peak of 450 nm as an optical semiconductor device, were bonded by die bonding on the surface of the first leads of the substrate for an optical semiconductor apparatus according to the present invention manufactured as above, and the die bonding agent was cured at 150° C. for 4 hours.

By wire bonding using a wire bonder (gold wire: FA 25 μm, product of TANAKA DENSHI KOGYO K.K.), the first electrodes of the optical semiconductor devices were each electrically connected with the first leads of the substrate for an optical semiconductor apparatus, and the second electrodes of the optical semiconductor devices were each electrically connected with the second leads of the substrate for an optical semiconductor apparatus. Here, as mentioned below in detail, the bonding strength of the gold wire subjected to wire bonding was measured.

A silicone sealing material (KER2500, product of Shin-Etsu Chemical Co., Ltd.) was coated on the optical semiconductor devices bonded by wire bonding with a suitable amount, and cured at 150° C. for 4 hours to obtain an optical semiconductor apparatus in which a plurality of the optical semiconductor devices sealed with the resin were arranged in a matrix state.

Subsequently, the obtained optical semiconductor apparatus was cut by a dicing process using a rotary blade while the thermosetting resin portion including the tie bar is used as a cutting margin, cleaned and dried to obtain an optical semiconductor apparatus each having one optical semiconductor device (outside dimension of 4.0×1.4×1.2 mm as a package). This optical semiconductor apparatus was thin and had high product-dimensional accuracy.

### Example 2

A substrate for an optical semiconductor apparatus was manufactured in the same conditions as in Example 1 except that degrease cleaning was not performed, and by using the substrate for an optical semiconductor apparatus, an optical semiconductor apparatus was manufactured in the same conditions as in Example 1.

The manufactured substrate for an optical semiconductor apparatus as above was molded without an unfilled portion of the thermosetting resin, air remaining, and a flash burr. Also, when the glossiness of the metal plating was measured, it was 1.38; it was confirmed that reduction in the glossiness was inhibited as compared with the results of the later-described Comparative Examples 1 to 3.

Also, the obtained optical semiconductor apparatus was thin and had high product-dimensional accuracy.

### Comparative Example 1

A substrate for an optical semiconductor apparatus was manufactured in the same conditions as in Example 1 except that the resin molding was carried out by transfer molding and as the degreasing treatment, electrolytic degreasing was carried out under conditions of 1 A and 30 seconds, and by using the substrate for an optical semiconductor apparatus, an optical semiconductor apparatus was manufactured in the same conditions as in Example 1.

The substrate for an optical semiconductor apparatus manufactured as above had no unfilled portion and air remaining of the thermosetting resin, but when the front and back surfaces of the lead was observed by a scanning type electron microscope (SEM), the flash burr was seen on the surface of the leads both before and after electrolytic degreasing.

In addition, when the glossiness of the metal plating was observed, it was 1.24, which was lowered as compared with those of Examples 1 and 2.

### Comparative Example 2

A substrate for an optical semiconductor apparatus was manufactured in the same conditions as in Example 1 except that the resin molding was carried out by transfer molding without degreasing treatment, and by using the substrate for an optical semiconductor apparatus, an optical semiconductor apparatus was manufactured in the same conditions as in Example 1.

The substrate for an optical semiconductor apparatus manufactured as above had no unfilled portion and air remaining of the thermosetting resin, but when the front and back surfaces of the leads was observed by a scanning type electron microscope (SEM), the flash burr was seen on the front surface of the lead.

Also, when the glossiness of the metal plating was measured, it was 1.17, which was lowered as compared with those of Examples 1 and 2.

### Comparative Example 3

A substrate for an optical semiconductor apparatus was manufactured in the same conditions as in Example 1 except that the resin molding was carried out by transfer molding without degreasing treatment, and by using the substrate for an optical semiconductor apparatus, an optical semiconductor apparatus was manufactured in the same conditions as in Example 1.

The substrate for an optical semiconductor apparatus manufactured as above had no unfilled portion and air remaining of the thermosetting resin, but when the front and back surfaces of the leads were observed by a scanning type electron microscope (SEM), the flash burr was seen on the front surface of the leads.

For the purpose of removing the flash burr, a wet blast treatment was then carried out by using a chemical solution containing spherical glass having an average grain size of 10 μm. When the front and back surfaces of the leads of the substrate for an optical semiconductor apparatus subjected to the wet blast treatment was observed by a scanning type electron microscope (SEM), no flash burr was seen on the front and back surfaces of the leads. However, the glossiness of the metal plating was measured, it was 1.15 and the glossiness of the metal plating was lost. The glossiness was thus lowered as compared with those of Examples 1 and 2.

### (Measurements of Total Luminous Flux Value and Wire Bonding Strength)

The total luminous flux values of the optical semiconductor apparatuses manufactured in the above-mentioned Examples 1 and 2 and Comparative Examples 1 to 3 were measured by using the total luminous flux measurement system HM-9100 (made by OTSUKA ELECTRONICS, CO., LTD.) (Applied electric current IF=20 mA). The measured points were 40 points, and its average value and a its standard deviation were calculated.

Also, in the state before coating a sealing material in the manufacturing process of the optical semiconductor apparatus as above, the bonding strength of the gold wire, subjected to wire bonding, of the optical semiconductor apparatus was measured by using a wire pull measurement system of a bond tester SIREIS 4000 manufactured by DAGE Corporation. The measured points were 40 points, and its average value and its standard deviation were calculated.

The results of the total luminous flux value and the wire bonding strength are shown in Table 1. As shown in Table i, the optical semiconductor apparatuses of Examples 1 and 2 manufactured by injection molding without generating a burr had larger total luminous flux values (i.e., brighter) as compared with those of Comparative Examples 1 to 3, and exhibited larger wire bonding strength values stably.

On the other hand, the optical semiconductor apparatuses of Comparative Examples 1 and 2 in which the flash burr remained on its surfaces of the leads had smaller total luminous flux values (i.e., darker) as compared with those of Examples 1 and 2, and exhibited smaller wire bonding strengths with larger standard deviations. This means they were markedly poor in reliability. In addition, the optical semiconductor apparatus of Comparative Example 3 in which the flash burr was removed by the wet blast treatment exhibited a large wire bonding strength value but a small total luminous flux value.

TABLE 1

| | | | | Comparative | Comparative | Comparative |
|---|---|---|---|---|---|---|
| | | Example 1 | Example 2 | Example 1 | Example 2 | Example 3 |
| Molding method | | Injection | Injection | Transfer | Transfer | Transfer |
| | | molding | molding | molding | molding | molding |
| Post-treatment | | Alkali | None | Electrolytic | None | Wet |
| | | cleaning | | degreasing | | blast |
| Flash burr | | None | None | Present | Present | None |
| remaining | | | | | | |
| Glossiness N = 5 | | 1.39 | 1.38 | 1.24 | 1.17 | 1.15 |
| Total | Lm | 0.654 | 0.636 | 0.593 | 0.581 | 0.561 |
| luminous | Standard | 0.006 | 0.015 | 0.023 | 0.026 | 0.023 |
| flux | deviation | | | | | |
| value | | | | | | |
| N = 40 | | | | | | |
| Wire | mN | 86.3 | 83.2 | 56.5 | 62.5 | 85.7 |
| pull | Standard | 4.8 | 6.5 | 17.2 | 16.1 | 5.2 |
| strength | deviation | | | | | |
| N = 40 | | | | | | |

It is to be noted that the present invention is not limited to the foregoing embodiment. The embodiment is just an exemplification, and any examples that have substantially the same feature and demonstrate the same functions and effects as those in the technical concept described in claims of the present invention are included in the technical scope of the present invention.

What is claimed is:

1. A substrate for an optical semiconductor apparatus for mounting optical semiconductor devices, the substrate comprising first leads to be electrically connected to first electrodes of the optical semiconductor devices and second leads to be electrically connected to second electrodes of the optical semiconductor devices, wherein
the first leads and the second leads are arranged each in parallel, a molded body of a thermosetting resin composition is molded in a penetrating gap between the first leads and the second leads, a reflector of the thermosetting resin composition is molded at a periphery of respective regions on which the optical semiconductor devices are to be mounted, and the resin molded body and the reflector are integrally molded with the first leads and the second leads by injection molding.

2. The substrate for an optical semiconductor apparatus according to claim 1, wherein metal plating having a glossiness of 1.0 or more is applied onto surfaces of the first leads and the second leads.

3. The substrate for an optical semiconductor apparatus according to claim 1, wherein the first leads and the second leads each have a step, a taper portion or a concave portion at their side surfaces in a thickness direction.

4. The substrate for an optical semiconductor apparatus according to claim 2, wherein the first leads and the second leads each have a step, a taper portion or a concave portion at their side surfaces in a thickness direction.

5. The substrate for an optical semiconductor apparatus according to claim 1, wherein the first leads and the second leads arranged each in parallel are connected to a frame-shaped frame through a tie bar having a thickness thinner than the thicknesses of the first leads and the second leads.

6. The substrate for an optical semiconductor apparatus according to claim 4, wherein the first leads and the second leads arranged each in parallel are connected to a frame-shaped frame through a tie bar having a thickness thinner than the thicknesses of the first leads and the second leads.

7. The substrate for an optical semiconductor apparatus according to claim 1, wherein the thermosetting resin composition is at least one selected from the group consisting of a silicone resin, an organic modified silicone resin, an epoxy resin, a modified epoxy resin, an acrylate resin and an urethane resin.

8. The substrate for an optical semiconductor apparatus according to claim 6, wherein the thermosetting resin composition is at least one selected from the group consisting of a silicone resin, an organic modified silicone resin, an epoxy resin, a modified epoxy resin, an acrylate resin and an urethane resin.

9. The substrate for an optical semiconductor apparatus according to claim 1, wherein the cured thermosetting resin contains at least one of an inorganic filler and a diffusing agent, the inorganic filler is at least one selected from the group consisting of silica, alumina, magnesium oxide, antimony oxide, aluminum hydroxide, barium sulfate, magnesium carbonate and barium carbonate, and the diffusing agent is at least one selected from the group consisting of barium titanate, titanium oxide, aluminum oxide and silicon oxide.

10. The substrate for an optical semiconductor apparatus according to claim 8, wherein the cured thermosetting resin contains at least one of an inorganic filler and a diffusing agent, the inorganic filler is at least one selected from the group consisting of silica, alumina, magnesium oxide, antimony oxide, aluminum hydroxide, barium sulfate, magnesium carbonate and barium carbonate, and the diffusing agent is at least one selected from the group consisting of barium titanate, titanium oxide, aluminum oxide and silicon oxide.

11. An optical semiconductor apparatus comprising an optical semiconductor device mounted on a first lead of the substrate for an optical semiconductor apparatus according to claim 1, a first electrode and a second electrode of the optical semiconductor devices are electrically connected to the first lead and a second lead, respectively, by wire bonding or flip chip bonding, and the optical semiconductor device is sealed by a resin or subjected to lens molding.

12. An optical semiconductor apparatus comprising an optical semiconductor device mounted on a first lead of the substrate for an optical semiconductor apparatus according to claim 10, a first electrode and a second electrode of the optical semiconductor devices are electrically connected to the first lead and a second lead, respectively, by wire bonding or flip chip bonding, and the optical semiconductor device is sealed by a resin or subjected to lens molding.

13. A method for manufacturing a substrate for an optical semiconductor apparatus for mounting optical semiconductor devices, the substrate including first leads to be electrically connected to first electrodes of the optical semiconductor devices and second leads to be electrically connected to second electrodes of the optical semiconductor devices, the method comprising
arranging the first leads and the second leads each in parallel, and
molding a molded body of a thermosetting resin composition in a penetrating gap between the first leads and the second leads, and a reflector of the thermosetting resin composition at a periphery of respective regions on which the optical semiconductor devices are to be mounted by injection molding to integrally mold the resin molded body and the reflector with the first leads and the second leads.

14. The method for manufacturing a substrate for an optical semiconductor apparatus according to claim 13, wherein metal plating having a glossiness of 1.0 or more is applied onto surfaces of the first leads and the second leads.

15. The method for manufacturing a substrate for an optical semiconductor apparatus according to claim 13, wherein after the resin molded body and the reflector are molded, the integrally molded substrate for an optical semiconductor apparatus is subjected to at least one of cleaning treatments of chemical solution cleaning with an acid or an alkali and electrolytic degreasing.

16. The method for manufacturing a substrate for an optical semiconductor apparatus according to claim 14, wherein after the resin molded body and the reflector are molded, the integrally molded substrate for an optical semiconductor apparatus is subjected to at least one of cleaning treatments of chemical solution cleaning with an acid or an alkali and electrolytic degreasing.

17. The method for manufacturing a substrate for an optical semiconductor apparatus according to claim 13, wherein the first leads and the second leads having a step, a taper portion, or a concave portion at their side surfaces in a thickness direction are used.

18. The method for manufacturing a substrate for an optical semiconductor apparatus according to claim 16, wherein the first leads and the second leads having a step, a taper portion, or a concave portion at their side surfaces in a thickness direction are used.

19. The method for manufacturing a substrate for an optical semiconductor apparatus according to claim 13, wherein the first leads and the second leads are arranged each in parallel by connecting the first leads and the second leads to a frame-shaped frame through a tie bar having a thickness thinner than a thicknesses of the first leads and the second leads.

20. The method for manufacturing a substrate for an optical semiconductor apparatus according to claim 18, wherein the first leads and the second leads are arranged each in parallel by connecting the first leads and the second leads to a frame-shaped frame through a tie bar having a thickness thinner than a thicknesses of the first leads and the second leads.

21. The method for manufacturing a substrate for an optical semiconductor apparatus according to claim 13, wherein the thermosetting resin composition used is at least one selected from the group consisting of a silicone resin, an organic modified silicone resin, an epoxy resin, a modified epoxy resin, an acrylate resin and an urethane resin.

22. The method for manufacturing a substrate for an optical semiconductor apparatus according to claim 20, wherein the thermosetting resin composition used is at least one selected from the group consisting of a silicone resin, an organic modified silicone resin, an epoxy resin, a modified epoxy resin, an acrylate resin and an urethane resin.

23. The method for manufacturing a substrate for an optical semiconductor apparatus according to claim 13, wherein the cured thermosetting resin contains at least one selected from an inorganic filler and diffusing agent, the inorganic filler is at least one selected from the group consisting of silica, alumina, magnesium oxide, antimony oxide, aluminum hydroxide, barium sulfate, magnesium carbonate and barium carbonate, and the diffusing agent is at least one selected from the group consisting of barium titanate, titanium oxide, aluminum oxide and silicon oxide.

24. The method for manufacturing a substrate for an optical semiconductor apparatus according to claim 22, wherein the cured thermosetting resin contains at least one selected from an inorganic filler and diffusing agent, the inorganic filler is at least one selected from the group consisting of silica, alumina, magnesium oxide, antimony oxide, aluminum hydroxide, barium sulfate, magnesium carbonate and barium carbonate, and the diffusing agent is at least one selected from the group consisting of barium titanate, titanium oxide, aluminum oxide and silicon oxide.

25. A method for manufacturing an optical semiconductor apparatus comprising
mounting an optical semiconductor device on a first lead of the substrate for an optical semiconductor apparatus manufactured by the method according to claim 13,
electrically connecting a first electrode and a second electrode of the optical semiconductor device to the first lead and a second lead, respectively, by wire bonding or flip chip bonding, and
sealing the optical semiconductor device by a resin or subjecting the optical semiconductor device to lens molding.

26. A method for manufacturing an optical semiconductor apparatus comprising
mounting an optical semiconductor device on a first lead of the substrate for an optical semiconductor apparatus manufactured by the method according to claim 24,
electrically connecting a first electrode and a second electrode of the optical semiconductor device to the first lead and a second lead, respectively, by wire bonding or flip chip bonding, and
sealing the optical semiconductor device by a resin or subjecting the optical semiconductor device to lens molding.
